(19) United States
(12) Patent Application Publication
(10) Pub. No.: US 2008/0136339 A1
(43) Pub. Date: Jun. 12, 2008

(54) Organic EL display device

(76) Inventors: Toshiyuki Matsuura, Mobara (JP); Masahiro Tanaka, Chiba (JP); Sukekazu Aratani, Hitachiota (JP); Masao Shimizu, Hitachi (JP)

Correspondence Address: REED SMITH LLP, Suite 1400, 3110 Fairview Park Drive, Falls Church, VA, 22042, US

(21) Appl. No.: 11/984,161

(22) Filed: Nov. 14, 2007

(30) Foreign Application Priority Data
Nov. 14, 2006 (JP) 2006-307916

(51) Int. Cl. G09G 3/00; H01L 51/54

(52) U.S. Cl. 315/169.3; 313/504

(57) ABSTRACT

The invention allows a top-emission-type organic EL display device to use a chemically stable conductive film containing ITO for forming a lower electrode of an organic EL layer. The organic EL layer includes an electron injection layer, an electron transport layer, a light emission layer, a hole transport layer and a hole injection layer. An upper electrode which constitutes a transparent electrode is formed of an IZO film. A lower electrode adopts the two-layered structure consisting of a lower layer made of Al or an Al alloy having high reflectance and an upper layer formed of a chemically stable ITO film. To enable the injection of electrons from the ITO film which constitutes the lower electrode, the electron injection layer is formed using a film which is acquired by co-depositing Li and Alq3 at a molecular ratio of 3:1. Due to such a constitution, electrons can be injected from the ITO film thus realizing the top-emission-type organic EL display device.

### CLAIM OF PRIORITY

The present application claims priority from Japanese Application JP 2006-307916 filed on Nov. 14, 2006, the content of which is hereby incorporated by reference into this application.

### BACKGROUND OF THE INVENTION

The present invention relates to the pixel structure of an organic EL display device, and more particularly to the pixel structure of a top-emission-type organic EL display device.

Although a main stream of the conventional display device is a CRT, a liquid crystal display device, a plasma display device and the like which are flat display devices have been practically used in place of the CRT and a demand for such flat display devices is increasing. In addition to these display devices, developments and efforts for practical use of a display device which uses organic electro luminescence (hereinafter, referred to as organic EL display device) and a display device which arranges electron sources utilizing field emission in a matrix array and makes phosphors arranged on an anode emit light thus forming an image (hereinafter referred to as an FED display device) have been also in progress.

The organic EL display device has several features including a feature (1) that the organic EL display device is of a self-luminous type compared with liquid crystal and hence, a backlight is unnecessary, a feature (2) that a voltage necessary for emission of light is low, that is, equal to or below 10V and hence, the power consumption can be decreased, a feature (3) that compared with the plasma display device or the FED display device, the vacuum structure is unnecessary and hence, the organic EL display device is suitable for achieving the reduction of weight and the reduction of thickness, a feature (4) that a response time is short, that is, several micro seconds and hence, the organic EL display device exhibits the excellent motion picture property, and a feature (5) that the viewing angle is large, that is, 170 degrees or more.

FIG. 7 is a cross-sectional view of the pixel structure of a so-called bottom-emission-type organic EL display device which has been developed conventionally. FIG. 7 is a cross-sectional view of a pixel portion of the display device which drives organic EL using a thin film transistor (TFT) as a switching element. In FIG. 7, an undercoat 2 is applied to an upper surface of a glass substrate 1. The undercoat 2 plays a role of preventing impurities from a glass substrate from contaminating TFTs and the organic EL.

A source portion, a channel portion and a drain portion are formed on a semiconductor layer 3. A gate insulation film 4 is formed so as to cover the semiconductor layer 3, a gate electrode 5 is formed on the gate insulation film 4, and an interlayer insulation film 6 is formed so as to cover the gate electrode 5. While an SD line 7 is formed on the interlayer insulation film 6, the SD line 7 is connected with the source portion or the drain portion formed on the semiconductor layer 3 via a through hole formed in the interlayer insulation film 6 thus playing a role to take out a signal from the TFT. A passivation film 8 is formed to cover the SD line 7 thus protecting the whole TFT. While a transparent electrode (ITO) which constitutes a lower electrode 9 of an organic EL layer is formed on the passivation film 8, the transparent electrode 9 is connected with the SD line 7 via a through hole formed in the passivation film 8. Further, on the transparent electrode 9 and the passivation film 8, a bank 10 for separating respective pixels from each other is formed.

On a portion of the transparent electrode 9 where the bank 10 is not formed, an organic EL layer 11 which constitutes a light emitting portion is stacked. Then, a metal layer which constitutes an upper electrode 12 is formed on the organic EL layer 11. The organic EL layer 11 is generally formed of a plurality of layers and emits light when a voltage is applied between a cathode and an anode. Here, the lower electrode 9 is formed of a transparent electrode, and all of the passivation film 8, the interlayer insulation film 6 and the undercoat 2 are transparent and hence, light emitted from the organic EL layer 11 advances in the direction indicated by an arrow L in FIG. 7 (bottom emission). On the other hand, light which advances toward the upper electrode 12 is reflected on the metal layer which constitutes the upper electrode 12 and also advances in the direction indicated by an arrow L in FIG. 7.

The organic EL layer 11 is formed of a plurality of layers for enhancing light emission efficiency. As known examples of the organic EL layer relevant to the present invention, organic EL layers disclosed in patent document 1 (JP-A-2005-166637) and patent document 2 (JP-A-2005-123094) are named. That is, patent document 1 discloses the constitution of the organic EL layer which contains a Hall electron conversion-layer, while patent document 2 discloses a technique which forms a reaction generation layer in contact with a cathode thus decreasing a barrier against energy for injecting electrons.

### SUMMARY OF THE INVENTION

The bottom-emission-type organic EL display device described in the above-mentioned prior art has several drawbacks including following drawbacks. That is, a light emission effective region is limited due to the relationship with a switching element such as a TFT. Light from the EL may influence an operation of the TFT which is the switching element.

To the contrary, the top-emission-type organic EL display device is advantageous with respect to the brightness of the display device due to the formation of a light emission region also on a TFT which constitutes a switching element or the like. However, the top-emission-type organic EL display device has a drawback derived from the constitution that the cathode for the organic EL layer must be used as a lower electrode. That is, since the cathode is required to reflect light, the cathode is formed of a metal film. This metal film, that is, the lower electrode is liable to be easily influenced in a photolithography step such as etching or the like and hence, a surface of the metal film becomes unstable. Accordingly, the injection of electrons into the organic EL layer becomes unstable thus giving rise to a drawback that the light emission characteristic of light emitted from the organic EL layer becomes unstable.

The invention has been made to overcome the above-mentioned drawbacks and to provide a top-emission-type organic EL display device. To be more specific, the top-emission-type organic EL display device has following constitutions.

(1) In an organic EL display device in which organic EL layers are arranged on a substrate in a matrix array, lower electrodes and upper electrodes are formed on the substrate in a state that each organic EL layer is sandwiched between the lower electrode and the upper electrode, and voltages are applied to the lower electrodes and the upper electrodes to make the organic EL layers emit light thus forming an image, the organic EL layer is formed of a plurality of layers, and a layer of the organic EL layer which is brought into contact with the lower electrode is formed of a co-deposition film made of Li and tris (8-quinolinol) aluminum (hereinafter, abbreviated as Alq3).

(2) In the organic EL display device having the constitution (1), a molecular ratio between Li and Alq3 of the co-deposition film made of Li and Alq3 is set to a value larger than 1.

(3) In the organic EL display device having the constitution (1), a molecular ratio between Li and Alq3 of the co-deposition film made of Li and Alq3 is set to a value larger than 1 and smaller than 6.

(4) In the organic EL display device having the constitution (1), a molecular ratio between Li and Alq3 of the co-deposition film made of Li and Alq3 is approximately 3.

(5) In the organic EL display device having the constitution (1), a layer of the lower electrode which is brought into contact with the co-deposition film made of Li and Alq3 of the organic EL layer is formed of an ITO film.

(6) In the organic EL display device having the constitution (1), the lower electrode is formed of a plurality of layers, a layer of the lower electrode which is brought into contact with the co-deposition film made of Li and Alq3 of the organic EL layer is formed of an ITO film, and a metal film is formed on a lower portion of the ITO film.

(7) In the organic EL display device having the constitution (6), the metal film is made of Al or an Al alloy.

(8) In the organic EL display device having the constitution (6), the metal film is made of Ag or an Ag alloy.

(9) In the organic EL display device having the constitution (1), the upper electrode is made of any one of IZO, ITO and WO₃.

(10) In an organic EL display device in which organic EL layers are arranged on a substrate in a matrix array, cathodes and anodes are formed on the substrate in a state that each organic EL layer is sandwiched between the cathode and the anode, and voltages are applied to the cathodes and the anodes to make the organic EL layers emit light thus forming an image, the organic EL layer is formed of a plurality of layers, and a layer of the organic EL layer which is brought into contact with the cathode is formed of an electron injection layer which is formed of a co-deposition film made of Li and Alq3.

(11) In the organic EL display device having the constitution (10), the cathode is formed of a plurality of layers, and a layer of the cathode which is brought into contact with the co-deposition film made of Li and Alq3 is formed of an ITO film.

(12) In the organic EL display device having the constitution (10), the cathode is formed of a plurality of layers, a layer of the cathode which is brought into contact with the co-deposition film made of Li and Alq3 is formed of an ITO film, and a lower layer of the ITO film is made of Al or an Al alloy.

(13) In the organic EL display device having the constitution (10), a layer of the cathode which is brought into contact with the co-deposition film made of Li and Alq3 is made of Ag or an Ag alloy.

(14) In an organic EL display device in which organic EL layers are arranged on a substrate in a matrix array, lower electrodes and upper electrodes are formed on the substrate in a state that each organic EL layer is sandwiched between the lower electrode and the upper electrode, and voltages are applied to the lower electrodes and the upper electrodes to make the organic EL layers emit light thus forming an image, the organic EL layer includes an electron injection layer, an electron transport layer, a light emission layer, a hole transport layer and a hole injection layer, and the electron injection layer is formed of a co-deposition film made of Li and Alq3.

(15) In the organic EL display device having the constitution (14), a molecular ratio between Li and Alq3 of the co-deposition film made of Li and Alq3 is set to a value larger than 1.

(16) In the organic EL display device having the constitution (14), a molecular ratio between Li and Alq3 of the co-deposition film made of Li and Alq3 is set to a value larger than 1 and smaller than 6.

(17) In the organic EL display device having the constitution (14), a molecular ratio between Li and Alq3 of the co-deposition film made of Li and Alq3 is approximately 3.

(18) In the organic EL display device having the constitution (14), the lower electrode is formed of a plurality of layers, a layer of the lower electrode which is brought into contact with the co-deposition film made of Li and Alq3 of the organic EL layer is formed of an ITO film, and a metal film is formed on a lower portion of the ITO film.

(19) In the organic EL display device having the constitution (14), the upper electrode is made of any one of IZO, ITO and WO₃.

(20) In the organic EL display device having the constitution (14), a layer of the lower electrode which is brought into contact with the co-deposition film made of Li and Alq3 is made of Ag or an Ag alloy.

To explain advantageous effects acquired by the above-mentioned respective constitutions, they areas follows.

According to the constitutions (1) to (9), by forming the layer of the organic EL layer which is brought into contact with the lower electrode using the co-deposition film made of Li and Alq3, materials which belong to a wide range can be used as a material of the lower electrode and hence, the use of such a co-deposition film is largely advantageous for the realization of the top-emission-type organic EL display device. The use of the stable material such as ITO for forming the lower electrode is particularly advantageous for the realization of the top-emission-type organic EL display device. Further, by allowing the lower electrode to have the multi-layered structure, in addition to a role of injecting charges into the lower electrode, the lower electrode can realize the chemical stability and the high reflectance.

Although the ITO film is chemically stable, the ITO film exhibits a high work function and hence, the ITO film has been used for forming an anode conventionally. However, the ITO film has been considered inappropriate for forming a cathode. According to the constitutions (10) to (13), with the use of the co-deposition film made of Li and Alq3 for forming the electron injection layer of the organic EL film, the ITO film can be used for forming the cathode and hence, the use of the co-deposition film as the electron injection layer of the organic EL layer is largely advantageous for the realization of the top-emission-type organic EL display device. Further, with the use of the co-deposition film made of Li and Alq3 as the electron injection layer of the organic EL film, so long as a process allows, a metal layer formed of metal having high reflectance such as Al, an Al alloy, Ag, an Ag alloy or the like which is brought into contact with the electron injection layer can be used and hence, the use of the co-deposition film is largely advantageous for the realization of the top-emission-type organic EL display device.

According to the constitutions (14) to (20), the organic EL layer includes the electron injection layer, the electron transport layer, the light emission layer, the hole transport layer and the hole injection layer, and the electron injection layer is formed of the co-deposition film made of Li and Alq3. Accordingly, it is possible to acquire the emission of light from the organic EL layer with high efficiency. Further, materials which belong to a large range including ITO can be used as the cathode material and hence, such a constitution is largely advantageous for the realization of the top-emission-type organic EL display device.

### BRIEF DESCRIPTION OF THE DRAWINGS

FIG. 1 is a cross-sectional view of a pixel portion of the invention;

FIG. 2 is a schematic cross-sectional view of an organic EL layer of the invention;

FIG. 3 is a schematic view of an evaluation experiment relevant to the invention;

FIG. 4 is a view showing an advantageous effect acquired by the invention;

FIG. 5 is another view showing an advantageous effect acquired by the invention;

FIG. 6 is a plan view of an organic EL display device to which the constitution of the invention is applied; and

FIG. 7 is a cross-sectional view of a bottom-emission-type element.

### DESCRIPTION OF THE PREFERRED EMBODIMENTS

The invention is explained in detail in conjunction with embodiments.

### Embodiment 1

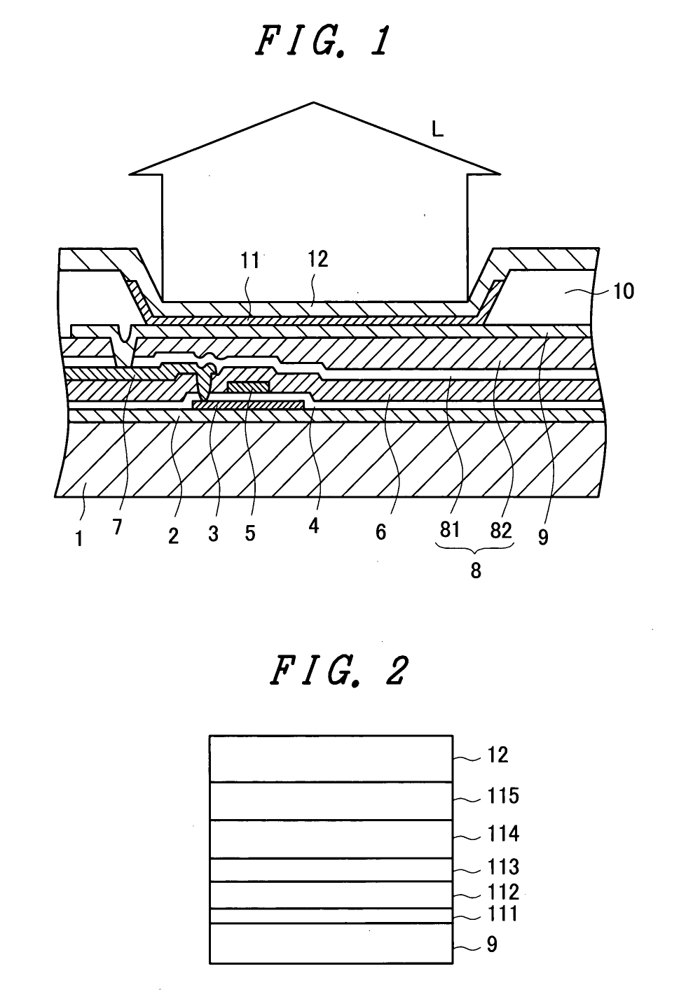

FIG. 1 shows the cross-sectional structure of a pixel portion of a top-emission-type organic EL display device according to the invention. In FIG. 1, a substrate 1 is made of glass in this embodiment. However, in case of the top-emission-type organic EL display device, the substrate 1 is not required to allow light to pass therethrough and hence, it is unnecessary to limit a material of the substrate 1 to glass and the substrate 1 may be made of metal such as stainless steel or a plastic material such as PET or PES. An undercoat 2 plays a role of a barrier against impurities from the substrate 1. On the other hand, it is important for the undercoat 2 to ensure adhesiveness with a semiconductor layer 3 formed thereon. In this embodiment, the undercoat 2 is formed of a silicon oxide film, a silicon nitride film or a stacked film constituted of the silicon oxide film and the silicon nitride film. When the two-layered film is used as the undercoat 2, a film thickness is formed such that, for example, the silicon nitride film which constitutes a lower layer has a thickness of 150 nm and the silicon oxide film which constitutes an upper layer has a thickness of 100 nm.

The semiconductor layer 3 is formed of an amorphous Si film which is produced by a CVD method, or a polysilicon film which is produced by annealing an amorphous Si film using a laser. A source portion or a drain portion to which conductivity is imparted by ion implantation is formed on both sides of the semiconductor layer 3. A film thickness of the semiconductor layer 3 is, for example, 50 nm.

A gate insulation film 4 is formed on the substrate 1 to cover the semiconductor layer 3. The gate insulation film 4 is formed of a silicon oxide film or a silicon nitride film produced by a CVD method, or a stacked film constituted of these films. A film thickness of the gate insulation film 4 is, for example, 100 nm. A gate metal layer which constitutes a gate electrode 5 is formed on the gate insulation film 4 by sputtering or the like. By patterning such a metal layer, it is possible to form not only the gate electrode 5 but also a gate line layer. As a material of a gate metal layer, a high-melting point metal such as Mo, W, Ta, Ti or an alloy of these metals may preferably be used. Still further, the gate metal layer may be formed of a stacked film constituted of these metals or an alloy of these metals. When the gate metal layer is also used as the terminal portion 12, it is necessary to form an uppermost layer using a stable material such as Ti, TiN, ITO or IZO. A film thickness of the gate electrode 5 is, for example, 150 nm.

An interlayer insulation film 6 is formed on the substrate 1 to cover the gate electrode 5. The interlayer insulation film 6 has a function of insulating a gate line which is connected to the gate electrode 5 and a signal line which is connected to a source-drain (SD) line layer 7. The interlayer insulation film 6 is formed of a silicon oxide film or a silicon nitride film which is produced by a CVD method. The film thickness of the interlayer insulation film 6 is, for example, 500 nm.

An SD metal layer which constitutes the SD line layer 7 is formed on the substrate 1 by sputtering or the like to cover the interlayer insulation film 6. The SD metal layer is formed into signal lines by patterning, and the SD metal layer is connected with the source portion or the drain portion of the semiconductor layer 3 via a through hole formed in the interlayer insulation film. A passivation film 8 for protecting the TFTs and the like is formed on the substrate 1 in a state that the passivation film 8 covers the SD line layer 7. In the top-emission-type organic EL display device of the invention, the organic EL layer 11 which constitutes a light emission layer is also formed on the TFT and hence, an upper surface of the passivation film 8 is required to be flat. Accordingly, the passivation film 8 is formed of two layers, wherein a lower layer 81 is formed of an inorganic film such as an SiN film and an upper layer 82 is formed of an organic passivation film such as an acrylic film and has an upper surface thereof flattened.

Further, on the flat organic passivation film 82, a line layer which constitutes a lower electrode 9 of the organic EL layer 11 is formed. The line layer which constitutes the lower electrode 9 is connected with the SD line layer 7 via a through hole formed in the passivation film 8. In the top-emission-type organic EL display device, the lower electrode 9 is required to possess following characteristics. That is, the lower electrode 9 is required to reflect light from the organic EL layer 11 and hence, it is necessary for the lower electrode 9 to possess the sufficient reflectance, the corrosion resistance against an etchant used for etching banks 10 formed on the lower electrode 9 or the passivation film or the like, the electron injecting characteristic with respect to the organic EL layer 11 and the like.

In this embodiment, to provide these characteristics to the lower electrode 9, the lower electrode 9 has the two-layered structure consisting of an Al film and an ITO film. Since Al possesses high conductivity and exhibits high reflectance of 90% or more, Al is suitable as a material of the lower electrode 9. However, Al exhibits poor resistance against the etchant used for forming the banks and hence, an ITO film is formed as a protective film of Al. Here, in place of Al, an Al alloy such as Al—Si or Ag or an Ag alloy may be used. However, these metals have similar drawbacks. The following explanation is made with respect to a case in which Al is used as the material of the lower electrode 9 as a typical example.

ITO is conductive and chemically stable and hence, ITO is preferable as a material of the protective film of Al. However, a work function of ITO is large, that is, the work function of ITO assumes a value which falls within a range from 4.7 eV to 5.3 eV. Accordingly, ITO is considered inappropriate as a material of a cathode conventionally but is considered appropriate as a material of an anode. However, according to the invention, due to the constitution of the organic EL film explained later, it is possible to use the ITO film for forming the lower electrode 9.

After forming the lower electrode 9 of the organic EL film, an acrylic film is coated for forming banks. The acrylic film is partially removed by etching. The lower electrode 9 of the organic EL film is exposed at a portion thereof where the acrylic film is removed. A portion where the acrylic film remains forms the bank 10 for separating the pixels.

The organic EL layer 11 is stacked on the exposed portion of the lower electrode 9 formed by removing the acrylic film. The organic EL layer 11 is formed of a plurality of films as explained later. Further, a transparent conductive film which constitutes an anode is formed on the organic EL layer 11. The invention is directed to the top-emission-type organic EL display device and hence, an upper electrode 12 which constitutes an anode is required to be formed of a transparent electrode. Further, the upper electrode 12 is required to exhibit high hole injecting efficiency for the organic EL layer 11. The upper electrode 12 is configured to apply a fixed DC voltage to the organic EL layer 11 and hence, it is unnecessary to separate the upper electrode 12 for every pixel. Further, since there exists a possibility that the upper electrode 12 is exposed to outside air, the upper electrode 12 is required to be also chemically stable. Further, the upper electrode 12 is required to exhibit the stable electric characteristic such as resistance for a longer period. As a material of the upper electrode 12 which can be used in this embodiment, ITO, IZO, WO₃ and the like are considered.

Light emitted from the organic EL is radiated in the direction indicated by an arrow L in FIG. 1. The top-emission-type organic EL display device is characterized in that a range that the organic EL layer 11 is stacked can be extended to a portion above the TFT. Accordingly, a light emission area can be increased and hence, it is possible to acquire a bright display device.

FIG. 2 is a schematic cross-sectional view showing a portion of the organic EL layer 11. In FIG. 2, an electron injection layer 111 is formed on the lower electrode 9. The electron injection layer 111 is provided for facilitating the injection of electrons from a cathode which constitutes the lower electrode 9. The electron injection layer 111 is formed by co-deposition such that a molecular ratio between tris (8-quinolinol) aluminum (hereinafter, abbreviated as Alq3) and Li assumes a relationship (2<Li/Alq3<4). A film thickness of the electron injection layer 111 is 3 nm.

An electron transport layer 112 is formed on the electron injection layer 111. The electron transport layer 112 is, for example, formed of an Alq3 layer having a film thickness of 20 nm which is formed by a vacuum vapor deposition method. This layer is provided for efficiently carrying electrons to a light emission layer 113 with the least resistance. The light emission layer 113 is formed on the electron transport layer 112. In this light emission layer 113, electrons and holes are re-coupled to generate the EL light emission. The light emission layer 113 is, for example, formed of a co-deposition film having a thickness of 20 nm which is made of Alq3 and quinacridone (abbreviated as Qc). A vapor-deposition speed ratio between Alq3 and Qc is 40:1. A hole transport layer 114 is formed on the light emission layer 113. The hole transport layer 114 is provided for efficiently carrying holes supplied from the anode to the light emission layer 113 with the least resistance. The hole transport layer 114 is formed of an α-NPD film having a thickness of 50 nm which is formed by vapor deposition. A hole injection layer 115 is formed on the hole transport layer 114. The hole injection layer 115 facilitates injection of holes from the anode. The hole injection layer 115 having a film thickness of 50 nm is formed of copper phthalo-cyanine by vapor deposition. The upper electrode 12 which constitutes the anode is formed on the hole injection layer 115.

Here, there may be a case in which a transparent metal oxide having a thickness of 15 nm is formed as a buffer layer by an electron beam (EB) vapor-deposition method or the like between the hole injection layer 115 and the upper electrode 12. As a material of metal oxide of the buffer layer, V₂O₅, MoO₃, WO₃ or the like is named. The buffer layer is mainly provided for preventing damages which the organic EL layer 11 receives in sputtering an anode material.

The invention is characterized by the provision of the electron injection layer 111. In this embodiment, out of the lower electrode 9, the ITO film is directly brought into contact with the organic EL layer 11. As has been described above, the ITO film has the large work function and hence, the ITO film is not used as the cathode but is used as the anode. However, in this embodiment, due to the reason that ITO is chemically stable, ITO is used as a material of the lower electrode 9, that is, as the material of the cathode. Conventionally, when the cathode is formed using Al or the like as a material, an electron injection layer having a layer thickness of 0.5 nm is formed by vacuum vapor-deposition using LiF as a material, for example. However, in using ITO as the material of the cathode, such an electron injection layer can not exhibit the sufficient characteristic.

Inventors of the invention have found out that with the use of the film which is formed by simultaneously vapor-depositing Li and Alq3 such that a fixed molecular ratio is acquired between Li and Alq3, even when ITO is used as the material of the cathode, the high electron injection efficiency can be obtained. A structural formula of Alq3 is expressed by a following chemical formula (1).

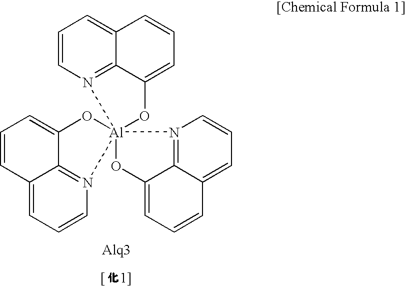

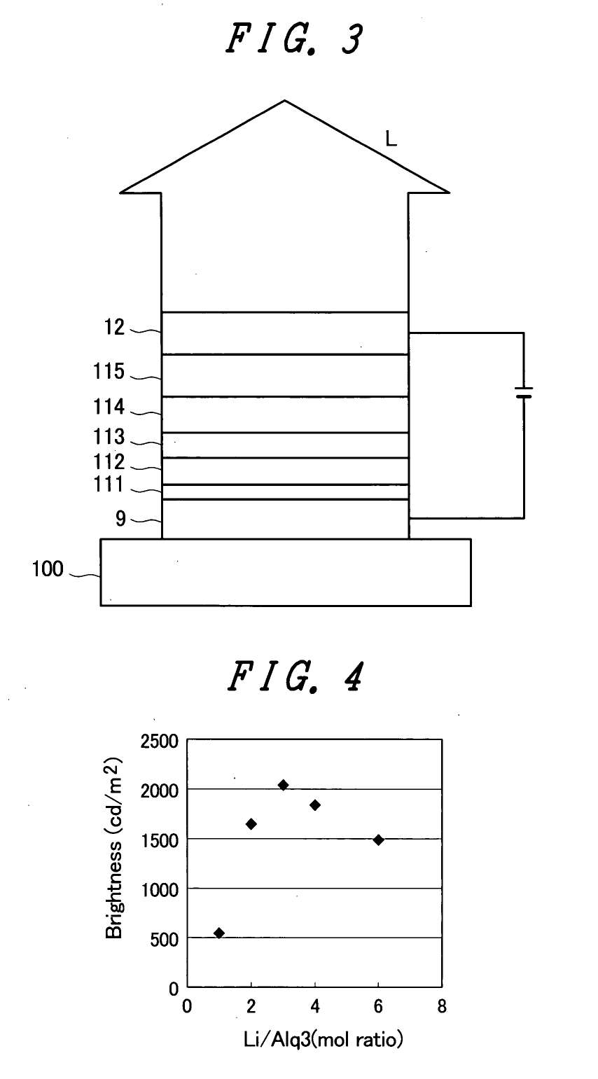

FIG. 3 is a schematic view showing light emission intensity of the organic EL film when the molecular ratio between Li and Alq3 in the electron injection layer 111 is changed. An ITO film is formed on a test glass substrate 100 as a lower electrode 9. Li and Alq3 are simultaneously vapor-deposited to form a film which constitutes the electron injection layer 111 on the ITO film such that a predetermined molecular ratio between Li and Alq3 is acquired. In forming the electron injection layer 111, vapor deposition speeds of Li and Alq3 are controlled such that the predetermined molecular ratio between L1 and Alq3 can be acquired. A film thickness of the electron injection layer 111 is set to 3 nm. In the same manner as the organic EL film shown in FIG. 2, an electron transport layer 112, a light emission layer 113, a hole transport layer 114 and a hole injection layer 115 are formed on the electron injection layer 111. An IZO film is formed as an anode.

In FIG. 3, the light emission intensity of the organic EL film is measured by changing the molecular ratio between Li and Alq3 while applying a voltage of 8V to the organic EL film. Although light from the light emission layer 113 is radiated upwardly and downwardly from the organic EL film, the brightnesses in the upward direction indicated by an arrow L shown in FIG. 3 when the molecular ratio between Li and Alq3 is changed are compared with each other.

FIG. 4 shows a result of measurement in which the predetermined molecular ratio (Li/Alq3) between Li and Alq3 is taken on an axis of abscissas and brightness is taken on an axis of ordinates. As shown in FIG. 4, along with the increase of Li/Alq3 from 1, the brightness is increased, and the brightness becomes maximum when the molecular ratio Li/Alq3 becomes approximately 3. Further, the organic EL film exhibits high brightness even when the molecular ratio Li/Alq3 is 6.

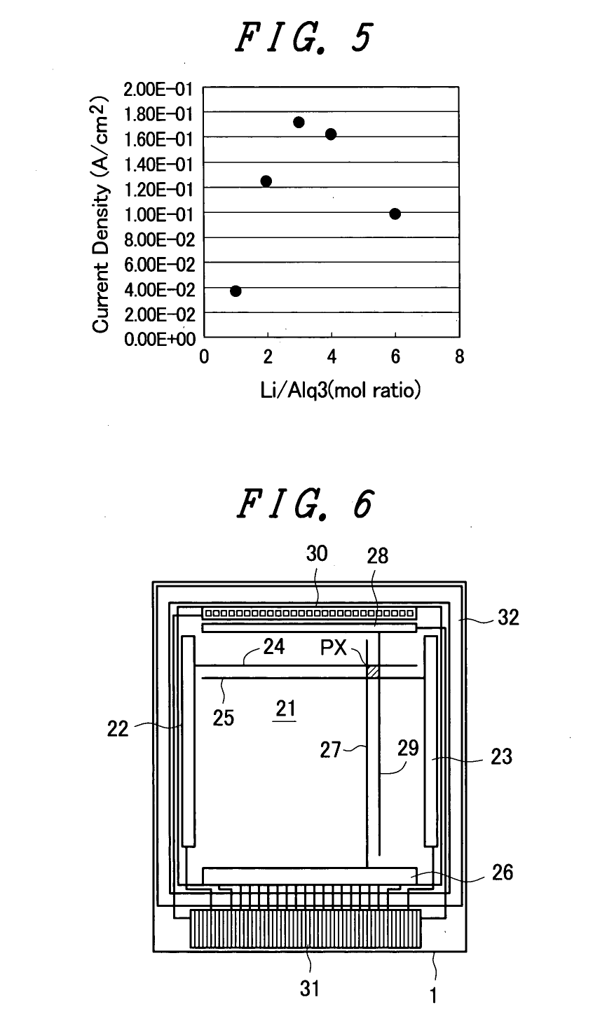

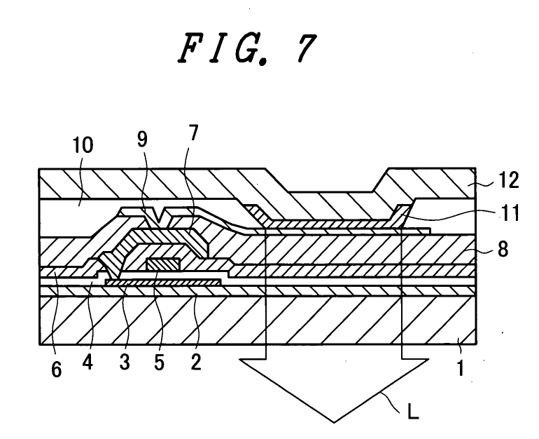

FIG. 5 is a graph showing a result of the measurement in which the molecular ratio between Li and Alq3 (Li/Alq3) is taken on an axis of abscissas and current density is taken on an axis of ordinates. As shown in FIG. 5, when the molecular ratio Li/Alq3 is approximately 3, the organic EL film acquires the maximum current density. Since the applied voltage is fixed, that is, 8V, the acquisition of the maximum current density implies that a potential barrier between the cathode and the electron injection layer 111 is minimum. That is, the organic EL film can acquire the maximum electron injection efficiency. As shown in FIG. 5, the electron injection efficiency is increased when the molecular ratio Li/Alq3 exceeds 1, and the electron injection quantity is still held at a high value even when the molecular ratio Li/Alq3 becomes 6.

Since Li possesses a small work function, that is 2.9 eV, Li is originally most suitable as an electron injection material. However, since Li is unstable, when Li is vapor-deposited on ITO, for example, Li is immediately oxidized so that the work function of Li is increased whereby the Li becomes an unsuitable material for forming the electron injection layer. To the contrary, according to the invention, by co-depositing Li and Alq3 at a suitable molecular ratio, the electron injection layer 111 can maintain the high injection efficiency.

The inventors of the invention estimate, as a reason that the electron injection layer 111 can maintain the high injection efficiency by co-depositing Li and Alq3 at the suitable molecular ratio, the generation of a material having a chemical formula (2) in the co-deposition layer.

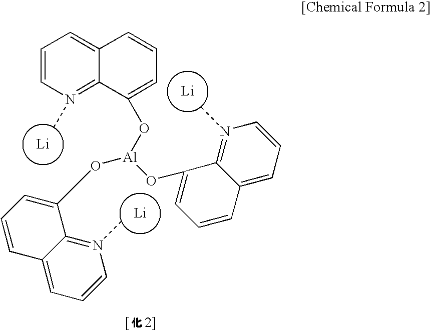

From the chemical formula (2), it is estimated that Li is trapped by Alq3 which is a metal complex so that the oxidation of Li is prevented and, at the same time, even when a voltage is applied to the organic EL film, Li is not moved to a cathode side. Further, this hypothesis agrees with a fact that when the molecular ratio of Li/Alq3 is 3, the electron injection efficiency becomes maximum.

The invention achieves a drastic advantageous effect with respect to a point that the high electron injection efficiency can be maintained even when oxide such as ITO is used as a material of a cathode by performing co-deposition of Li and Alq3 at an appropriate molecular ratio. The invention can acquire a remarkable advantageous effect with respect to the point that the cathode portion of the organic EL layer 11 of the top-emission type organic EL display device can be formed using the chemically stable conductive film.

### Embodiment 2

The embodiment 1 adopts the two-layered structure consisting of the ITO film and the Al film as the cathode of the organic EL layer 11. The reason that the two-layered film is used is that ITO is transparent and hence, the ITO film cannot reflect light emitted from the organic EL layer 11 upwardly whereby the metal film arranged below the ITO film is used as the reflection layer.

The lower electrode 9, that is, a cathode of the organic EL layer 11 is contaminated by an etchant, a resist peeling liquid or the like at the time of forming the banks 10 after the formation of the cathode. For example, when the cathode is formed of the Al film, depending on a kind of etchant or resist liquid, the cathode is dissipated. However, depending on a kind of etchant or resist liquid and conditions, there may be a case that the cathode maintains conductivity while having a surface thereof slightly oxidized.

When the cathode is formed using Al as a material thereof, conventionally, the electron injection layer 111 is formed of a vapor deposition film made of LiF having a thickness of approximately 0.5 nm. However, when a surface of the Al film is contaminated as in the case of the top-emission-type organic EL display device, the electron injection efficiency is lowered and hence, the organic EL display device cannot be practically used.

An organic EL film is formed such that a cathode is formed using Al which has a surface thereof contaminated by an etchant or a resist peeling liquid used for forming banks, and an electron injection layer 111 is made of Li and Alq3 at an appropriate molecular ratio. Then, an experiment shown in FIG. 4 is performed. As expected, the organic EL film acquires a result similar to the result acquired by the organic EL film which uses ITO as the material of the cathode, wherein the organic EL film exhibits the maximum light emission efficiency and the maximum electron injection efficiency when the molecular ratio of Li/Alq3 is approximately 3.

Further, when an experiment is performed with respect to cases in which the cathodes are made of alloy of Al and Si, Ag and Ag alloy, the organic EL films acquire results similar to the result acquired by the organic EL film which uses ITO as the material of the cathode.

That is, the electron injection layer 111 made of Li and Alq3 at an appropriate molecular ratio between Li and Alq3 can be used in conformity with materials for forming the cathode of the organic EL layer 11 in a wide range. However, in such a case, it is necessary that the electron injection layer 111 is formed of a material which is not dissipated by an etchant or a resist peeling liquid or a material which does not lose conductivity at the time of forming banks.

This embodiment is costly excellent with respect to a point that the cathode material of the organic EL film does not require the two-layered structure consisting of an ITO film and a metal film having high reflectance. Further, by incorporating the electron injection layer 111 made of Li and Alq3 at an appropriate molecular ratio into the organic EL layer 11, it is possible to maintain practical electron injection efficiency.

### Embodiment 3

FIG. 6 is an overall plan view of the organic EL display device having the pixels constituted by the invention. In assembling the organic EL display device, after completion of the substrate 1, the substrate 1 is hermetically sealed by a face glass together with a desiccant for protecting the organic EL layers 11 from moisture. FIG. 6 is a plan view showing the substrate 1 from above before the face glass is mounted. A display region 21 is formed on most of a center portion of the substrate 1. Scanning signal drive circuits 22, 23 are arranged on both sides of the display region. Gate signal line extends from the respective scanning signal drive circuits 22, 23. The gate signal lines 24 extending from the scanning signal drive circuit 22 on the left side and the gate signal lines 25 extending from the scanning signal drive circuit 23 on the right side are alternately arranged.

A video signal drive circuit 26 is arranged on a lower side of the display region 21, and data signal lines 27 extend toward a display region 21 side from the video signal drive circuit 26. On an upper side of the display region 21, a current supply bus line 28 is arranged and current supply lines 29 extend toward the display region 21 side from the current supply bus line 28.

The data signal lines 27 and the current supply lines 29 are alternately arranged. Due to such a constitution, a region of one pixel PX is formed in each region surrounded by these data signal line 27, current supply line 29, gate signal line 24 and gate signal line 25. A cross section of this pixel PX is shown in FIG. 1 which is a cross-sectional view.

A group of contact holes 30 is formed in an upper side of the display region. The group of contact holes 30 plays a role of electrically connecting the upper electrodes 12 of the organic EL layers 11 formed on a whole area of the display region and lines which are formed below an insulation film and extend to terminals. Terminals 31 are formed on a lower side of the display region, and scanning signals, data signals, anode potentials applied to the organic EL layers 11, cathode potentials applied to the organic EL layer 11 and the like are supplied from the terminals 31.

A sealing material 32 is formed on the substrate 1 such that the sealing material 32 surrounds the display region 21, the scanning signal drive circuits 22, 23, the video signal drive circuit 26, the current supply bus line 28, and portions which constitute frames for sealing the face glass and the substrate 1 are sealed to the sealing material 32. A terminal portion 31 is formed on the substrate 1 outside the sealing material 32, and signals and currents are supplied to the scanning signal drive circuits 22, 23, the video signal drive circuit 26, the current supply bus line 28 and the like from the terminal portion 31.

The organic EL display device of the invention is the top-emission-type organic EL display device and hence, light is radiated from a paper surface in FIG. 6. That is, a viewer observes an image through the face glass. Further, the organic EL display device of the invention is the top-emission-type organic EL display device and hence, the face glass is required to be transparent. However, the substrate 1 is not always necessary to be transparent.

As has been described heretofore, the invention uses the characteristic electron injection layers and hence, the materials in a wide range can be used as the material of the cathodes thus realizing the top-emission-type organic EL display device which exhibits high brightness.

What is claimed is:

1. An organic EL display device in which organic EL layers are arranged on a substrate in a matrix array, lower electrodes and upper electrodes are formed on the substrate in a state that each organic EL layer is sandwiched between the lower electrode and the upper electrode, and voltages are applied to the lower electrodes and the upper electrodes to make the organic EL layers emit light thus forming an image, wherein the organic EL layer is formed of a plurality of layers, and a layer of the organic EL layer which is brought into contact with the lower electrode is formed of a co-deposition film made of Li and Alq3.

2. An organic EL display device according to claim 1, wherein a molecular ratio between Li and Alq3 of the co-deposition film made of Li and Alq3 is set to a value larger than 1.

3. An organic EL display device according to claim 1, wherein a molecular ratio between Li and Alq3 of the co-deposition film made of Li and Alq3 is set to a value larger than 1 and smaller than 6.

4. An organic EL display device according to claim 1, wherein a molecular ratio between Li and Alq3 of the co-deposition film made of Li and Alq3 is approximately 3.

5. An organic EL display device according to claim 1, wherein a layer of the lower electrode which is brought into contact with the co-deposition film made of Li and Alq3 of the organic EL layer is formed of an ITO film.

6. An organic EL display device according to claim 1, wherein the lower electrode is formed of a plurality of layers, a layer of the lower electrode which is brought into contact with the co-deposition film made of Li and Alq3 of the organic EL layer is formed of an ITO film, and a metal film is formed on a lower portion of the ITO film.

7. An organic EL display device according to claim 6, wherein the metal film is made of an Al or an Al alloy.

8. An organic EL display-device according to claim 6, wherein the metal film is made of Ag or an Ag alloy.

9. An organic EL display device according to claim 1, wherein the upper electrode is made of any one of IZO, ITO and WO₃.

10. An organic EL display device in which organic EL layers are arranged on a substrate in a matrix array, cathodes and anodes are formed on the substrate in a state that each organic EL layer is sandwiched between the cathode and the anode, and voltages are applied to the cathodes and the anodes to make the organic EL layers emit light thus forming an image, wherein
the organic EL layer is formed of a plurality of layers, and a layer of the organic EL layer which is brought into contact with the cathode is formed of an electron injection layer which is formed of a co-deposition film made of Li and Alq3.

11. An organic EL display device according to claim 10, wherein the cathode is formed of a plurality of layers, and a layer of the cathode which is brought into contact with the co-deposition film made of Li and Alq3 is formed of an ITO film.

12. An organic EL display device according to claim 10, wherein the cathode is formed of a plurality of layers, a layer of the cathode which is brought into contact with the co-deposition film made of Li and Alq3 is formed of an ITO film, and a lower layer of the ITO film is made of Al or an Al alloy.

13. An organic EL display device according to claim 10, wherein a layer of the cathode which is brought into contact with the co-deposition film made of Li and Alq3 is made of Ag or an Ag alloy.

14. An organic EL display device in which organic EL layers are arranged on a substrate in a matrix array, lower electrodes and upper electrodes are formed on the substrate in a state that each organic EL layer is sandwiched between the lower electrode and the upper electrode, and voltages are applied to the lower electrodes and the upper electrodes to make the organic EL layers emit light thus forming an image, wherein
the organic EL layer includes an electron injection layer, an electron transport layer, a light emission layer, a hole transport layer and a hole injection layer, and the electron injection layer is formed of a co-deposition film made of Li and Alq3.

15. An organic EL display device according to claim 14, wherein a molecular ratio between Li and Alq3 of the co-deposition film made of Li and Alq3 is set to a value larger than 1.

16. An organic EL display device according to claim 14, wherein a molecular ratio between Li and Alq3 of the co-deposition film made of Li and Alq3 is set to a value larger than 1 and smaller than 6.

17. An organic EL display device according to claim 14, wherein a molecular ratio between Li and Alq3 of the co-deposition film made of Li and Alq3 is approximately 3.

18. An organic EL display device according to claim 14, wherein the lower electrode is formed of a plurality of layers, a layer of the lower electrode which is brought into contact with the co-deposition film made of Li and Alq3 of the organic EL layer is formed of an ITO film, and a metal film is formed on a lower portion of the ITO film.

19. An organic EL display device according to claim 14, wherein the upper electrode is made of any of IZO, ITO and WO₃.

20. An organic EL display device according to claim 14, wherein a layer of the lower electrode which is brought into contact with the co-deposition film made of Li and Alq3 is made of Ag or an Ag alloy.
